(19) United States
(12) Patent Application Publication
(10) Pub. No.: US 2007/0105259 A1
(43) Pub. Date: May 10, 2007

(54) Growth method of indium gallium nitride

(75) Inventors: Jong Hak Won, Yongin (KR); Masayoshi Koike, Suwon (KR); Jae Woong Han, Sungnam (KR); Seong Suk Lee, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/591,455

(22) Filed: Nov. 2, 2006

(30) Foreign Application Priority Data
Nov. 7, 2005 (KR) 10-2005-0106154

(51) Int. Cl. H01L 21/205

(52) U.S. Cl. 438/46; 438/478; 438/483

(57) ABSTRACT

A method for growing a high quality indium gallium nitride by metal organic chemical vapor deposition (MOCVD) is provided. In the method, the indium gallium nitride grows at a growth rate of at least about 1.5 nm/min at a temperature of at least about 800° C. while an internal pressure of an MOCVD reactor is maintained at about 400 mbar or less.

### CLAIM OF PRIORITY

This application claims the benefit of Korean Patent Application No. 2005-106154 filed on Nov. 7, 2005 in the Korean Intellectual Property Office, the disclosure of which is incorporated herein by reference.

### BACKGROUND OF THE INVENTION

1. Field of the Invention

The present invention relates to a method for manufacturing an InGaN-based nitride, and more particularly, to an indium gallium nitride having uniform composition and excellent crytallinity which can be employed in a light emitting diode or laser diode.

2. Description of the Related Art

In general, an indium gallium nitride having a composition expressed by In₁₋ₓGaₓN, 0x<1 is utilized in forming a quantum well in a light emitting diode (LED) and a laser diode (LD). The indium gallium nitride semiconductor has its emission wavelength determined by Indium content. More specifically, emission wavelength of an indium gallium nitride (InGaN) quantum well layer tends to be lengthened by increase in the Indium content.

FIG. 1 is a side sectional view illustrating a conventional nitride semiconductor light emitting diode structure.

As shown in FIG. 1, the nitride semiconductor light emitting diode 10 includes a sapphire substrate 11, a first conductivity type nitride layer 13, an active layer 15 of a multiple quantum well structure and a second conductivity type nitride layer 17. The second nitride semiconductor layer 17 is mesa-etched and a first electrode 19a is formed on the mesa-etched second nitride semiconductor layer. The first conductivity type nitride semiconductor layer 13 has a transparent electrode layer 18 and a second electrode 19b formed sequentially thereon.

Here, the active layer 15 made of a multiple quantum well structure has an undoped GaN barrier layer 15a and an undoped InGaN quantum well layer 15b stacked alternately thereon. As just described, the emission wavelength of the quantum well layer 15b is mainly determined by variation in In content.

A solid solution of such indium gallium nitride is thermodynamically unstable and thus separated into two types of spontaneously stable phases. Due to this phase separation, phases with great In content are unevenly distributed on a matrix with small In content. Especially, Indium of the indium gallium nitride exhibits a lower vapor pressure than that of gallium. Accordingly, when supply of a material for the quantum well layer is suspended for growth of the quantum barrier layer, indium atoms are easily volatilized from a surface of the indium gallium nitride, thereby rendering overall compositional distribution uneven and degrading crystallinity.

As described above, the indium gallium nitride is hardly grown with high crystallinity and uniform compositional distribution. The aforesaid problem is aggravated when the Indium content is increased to emit light of long wavelength.

### SUMMARY OF THE INVENTION

The present invention has been made to solve the foregoing problems of the prior art and it is therefore an object according to certain embodiments of the present invention is to provide a method for growing an indium gallium nitride (InGaN) with fewer defects and uniform compositional distribution by optimizing growth conditions such as a growth rate and internal pressure, and restraining atoms from being volatilized from a surface of the indium gallium nitride.

According to an aspect of the invention for realizing the object, there is provided a method for growing an indium gallium nitride by metal organic chemical vapor deposition comprising: growing the indium gallium nitride at a rate of at least about 1.5 nm/min and at a temperature of at least about 800° C. while maintaining an MOCVD reactor at an internal pressure of about 400 mbar or less.

Preferably, the growth rate of the indium gallium nitride is at least about 2 nm/min.

Preferably, the internal pressure of the MOCVD reactor is about 300 mbar or less. This low internal pressure prevents atomic collision that may cause indium atoms to be volatized from a surface of the indium gallium nitride and sufficiently assures a high growth rate.

Preferably, to achieve high-quality crystalline growth, the growth temperature of the indium gallium nitride is about 820° C. or more. This produces a high-quality nitride crystal growth due to sufficient suppression of volatilization of indium atoms. Notably, unlike a conventional process, this high growth temperature reduces a time of ramping, which is a necessary process for growing the quantum barrier layer of e.g., GaN. Thus, this abates conditions in which indium atoms may be volatilized.

As described above, according to the invention, the indium gallium nitride is grown at a rate of about 1.5 nm/min and under a low internal pressure and a high temperature of 800° C. or more which is higher than a conventional growth temperature of about 750° C. This prevents indium atoms from being volatilized from a surface of the indium gallium nitride, thereby producing the indium gallium nitride with even compositional ratio and better crytallinity.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a side sectional view illustrating a conventional nitride semiconductor light emitting diode;

FIG. 2 is a graph illustrating change in light emitting properties of an indium gallium nitride in accordance with a growth rate;

FIGS. 3a and 3b are SEM pictures illustrating an indium gallium nitride grown at a low growth rate of 1 nm/min;

FIGS. 4a and 4b are SEM pictures illustrating an indium gallium nitride grown at a rate of 2.5 nm/min according to the invention;

FIGS. 5a and 5b are pictures illustrating light emission of the indium gallium nitride shown in FIGS. 3a and 4a; and

FIG. 6 is a graph illustrating change in light emission properties of an indium gallium nitride in accordance with an internal pressure of a reactor.

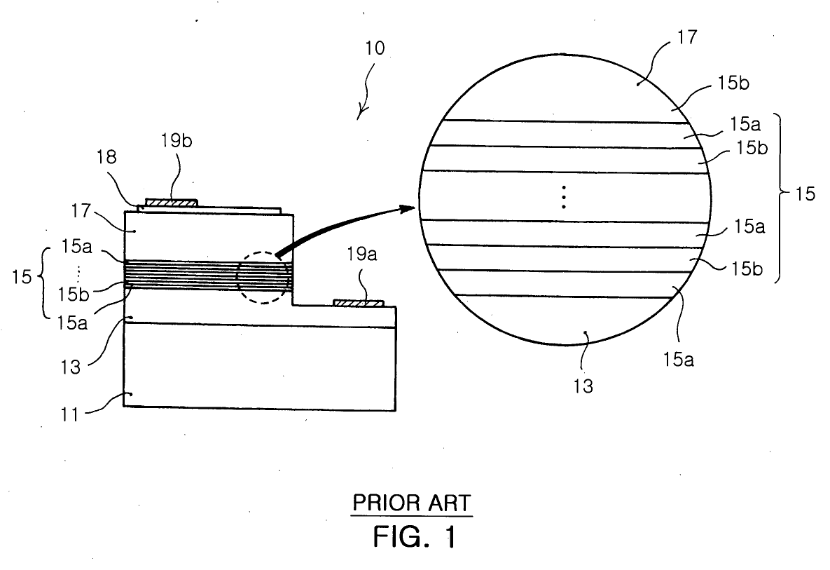

### DETAILED DESCRIPTION OF THE PREFERRED EMBODIMENT

Examples of the present invention will now be described in detail with reference to the accompanying drawings.

### EXAMPLE 1

In Example 1, to confirm effects of a method for growing an indium gallium nitride according to the invention, the indium gallium nitride was grown under equal conditions except a growth rate. This growth process was carried out via metal organic chemical vapor deposition (MOCVD).

First, a sapphire substrate with its surface cleaned was installed in an MOCVD reactor. Then in an ammonia (NH₃) atmosphere, only trimethyl gallium (TMGa) was supplied to grow a low temperature GaN buffer layer to a thickness of about 20 nm at a temperature of 550° C.

Subsequently, trimethyl gallium was supplied at a temperature of about 950° C. to grow GaN. Next, with an internal pressure of the reactor set at 400 mbar, trimethyl indium TMIn and trimethyl gallium were supplied in an ammonia atmosphere to grow In_{0.2}Ga_{0.8}N at a rate of 1 nm/min. Here, the indium content ratio of the indium gallium nitride was adjusted by an adequate ratio of trimethyl indium to trimethyl gallium. The growth rate was adjusted by a III/V ratio. In Example 1, In_{0.2}Ga_{0.8}Ns was grown under equal conditions except that a growth rate was varied into 1.5, 2.0, .2.5, 3.0, 3.5, 4.0 nm/min. For this purpose, a flow rate of trimethyl gallium TMGa was adjusted as noted in Table 1 while flow rates of TMIn and NH₃ were maintained constant.

TABLE 1

| | Growth rate (nm/min) | TMGa (μmol/min) |
|---|---|---|
| Sample 1 | 1.0 | 40.359 |
| Sample 2 | 1.5 | 60.539 |
| Sample 3 | 2.0 | 80.718 |
| Sample 4 | 2.5 | 100.898 |
| Sample 5 | 3.0 | 121.078 |
| Sample 6 | 3.5 | 141.101 |
| Sample 7 | 4.0 | 166.202 |

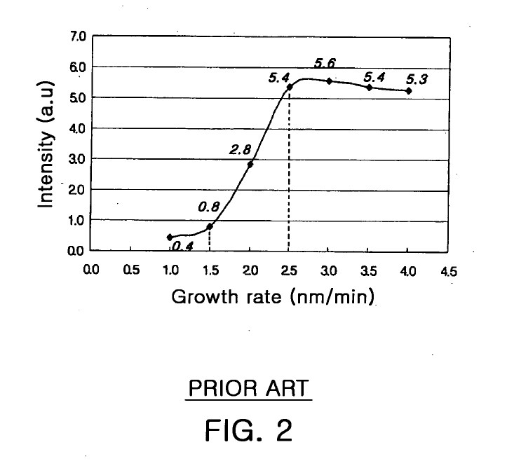

For In_{0.2}Ga_{0.8}Ns manufactured at different growth rates, light emission (PL) properties were measured, and FIG. 2 is a graph plotting light emission peak intensity in accordance with growth rates.

As shown in FIG. 2, the light emission peak started to increase steeply from a growth rate of 1.5 nm/min. That is, under a low internal pressure of 300 to 400 mbar and a low growth rate of 1.0 nm/min as in the prior art, the light emission peak intensity was plotted at merely 0.4. But the light emission peak intensity increased to 0.8 at a growth rate of 1.5 nm/min and to 5.4 at a growth rate of 2.5 nm/min. Also, the light emission peak intensity was moderately saturated at a growth rate exceeding 4 nm/min.

Out of samples obtained according to Example 1, comparison was made between the conventional indium gallium nitride grown at a rate of 1 nm/min and the indium gallium nitride of the invention grown at a rate of 2.5 nm/min in terms of the crystallinity and compositional ratio.

First, for crystallinity comparison, the two samples (first and fourth samples) were selected to photograph their crystallinity via SEM.

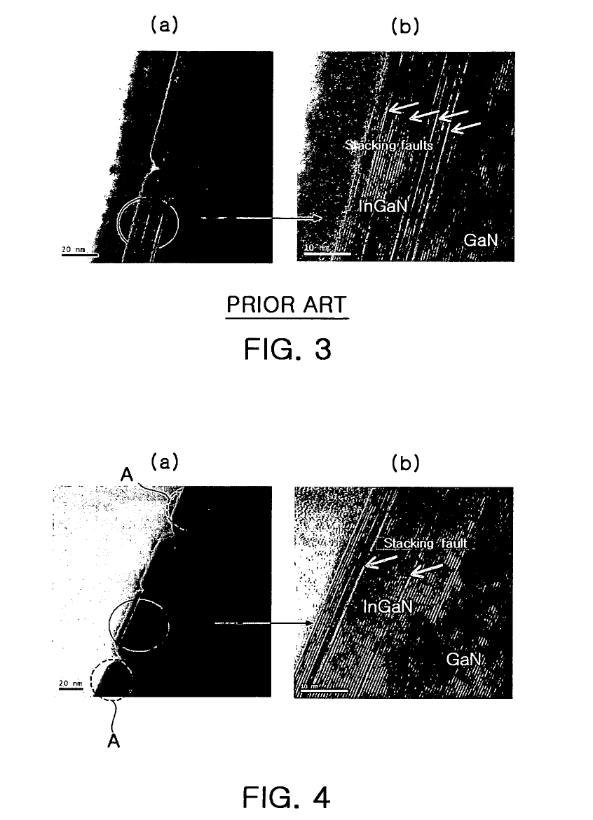

FIGS. 3a and 3b are SEM pictures illustrating the indium gallium nitride grown at a low rate of 1 nm/min. FIGS. 4a and 4b are SEM pictures illustrating the indium gallium nitride grown at a rate of 2.5 nm/min according to the invention. Here, FIGS. 3b and 4b are magnified pictures illustrating a circled portion of FIGS. 3a and 4b, respectively.

First, the indium gallium nitride of FIGS. 3a and 3b exhibits a number of stacking faults. On the other hand, the indium gallium nitride of FIGS. 4a and 4b shows relatively significant reduction in stacking fault density and even a portion A which is almost devoid of the stacking faults.

In this fashion, it is confirmed that cyrstallinity is remarkably improved by growing the indium gallium nitride at a high growth rate and under a relatively high temperature and low internal pressure.

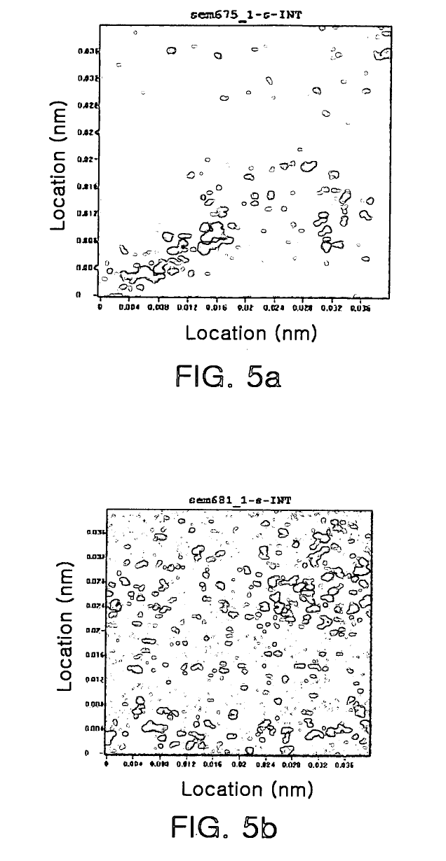

Afterwards, surfaces of the indium gallium nitrides of the two samples were photographed to measure light emission. FIGS. 5a and 5b are pictures illustrating light emission of the indium gallium nitride shown in FIGS. 3a and 4a, respectively.

Referring to FIGS. 5a and 5b, the indium gallium nitride (conventional) obtained at a growth rate of 1 nm/min emitted relatively small amount of red and yellow light with very uneven distribution across the entire area, compared with the indium gallium nitride obtained at a growth rate of 2.5 nm/min. This is because the indium gallium nitride of FIG. 5b was significantly reduced in stacking faults and also dislocation density and size. Especially this uniform light emission across the entire surface demonstrates a big decrease in the uneven compositional ratio resulting from volatilization of Indium atoms.

In the conventional sample 1 obtained at a growth rate of 1 nm/min in Example 1, the indium gallium nitride was grown under a low internal pressure and at a low rate as in the prior art but at a relatively high temperature. Thus indium atoms having a low vapor pressure were volatilized from a surface of the indium gallium nitride. However, the growth rate was increased to 1.5 nm/min or more, preferably 2.0 nm/min or more, more preferably to 2.5 nm/min or more. This inhibited volatilization of indium atoms, thereby producing the high quality indium gallium nitride even at a relatively high temperature.

Notably, compared to the prior art, the indium gallium nitride of the invention is grown at a relatively higher temperature of 800° C. or more, preferably 820° C. Thus the invention is beneficial for forming an active layer of a multiple quantum well structure in practice.

More specifically, a quantum barrier layer made of e.g., gallium nitride (GaN) needs to be grown at a high temperature, thereby requiring a time for ramping temperature after growing the indium gallium nitride quantum well layer. Here, a prolonged lamping time causes indium atoms to be volatilized more severely from a surface of the indium gallium nitride. However, according to the invention, the indium gallium nitride quantum well layer is grown at a relatively high temperature. This shortens the ramping time, thereby beneficially serving to achieve higher quality crsytallinity.

In this aspect, preferably, the indium gallium nitride is grown at a growth temperature similar to that of the gallium nitride. That is, in view of a low vapor pressure of indium, the indium gallium nitride quantum well layer is grown at a temperature of about 870° C. which is similar to that of the quantum barrier layer, on conditions that the indium gallium nitride quantum well layer is grown at a higher growth rate. This as a result ensures relatively high quality crystallinity.

### EXAMPLE 2

In Example 2, to confirm internal pressure conditions appropriate for growing an indium gallium nitride according to the invention, the indium gallium nitride was grown under equal conditions except an internal pressure.

Example 2 was carried out under conditions similar to those of Example 1. But a reactor was maintained at an internal pressure of 200 mbarr and a growth rate of the indium gallium nitride (In_{0.2}Ga_{0.8}N) was adjusted to 2.5 nm/min using a III/V ratio.

Also, the internal pressure of the reactor was varied into 300, 400 and 500 mbarr, respectively under the same conditions in order to produce three samples of indium gallium nitrides (In_{0.2}Ga_{0.8}N) (four samples in total)

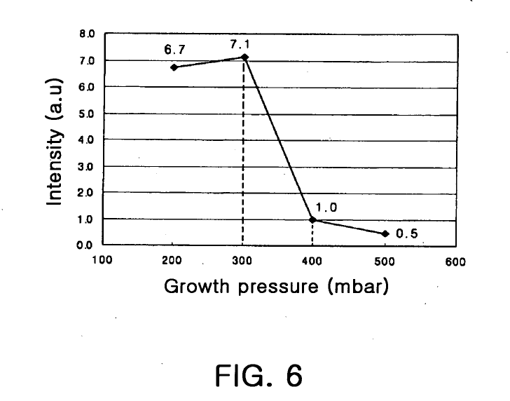

For each In_{0.2}Ga_{0.8}N manufactured under the internal pressure conditions, light emission (PL) properties were measured, and FIG. 6 illustrates light emission peak intensity in accordance with growth rates.

As shown in FIG. 6, the light emission peak intensity drastically decreased at an internal pressure exceeding 300 mbarr. Moreover, the light emission peak intensity was considerably reduced to 1.0 or less at an internal pressure exceeding 400 mbar.

This is because atoms are not effectively prevented from volatilization from a surface of the indium gallium nitride due to increased collision among precursors, i.e., a source at a high internal pressure. Therefore, a rise in the internal pressure leads to a decline in uniformity and crystallinity.

Consequently, as shown in FIG. 6, according to the invention, the reactor should have an internal pressure of 400 mbarr or less, preferably, 300 mbarr or less.

As set forth above, according to preferred embodiments of the invention, an indium gallium nitride is grown at a rate of 1.5 nm/min or more while maintaining a relatively high temperature and a low internal pressure, which is conducive to high quality crystallinity. This produces a superior indium gallium nitride having an overall uniform compositional ratio and significantly reduced crystal defects.

While the present invention has been shown and described in connection with the preferred embodiments, it will be apparent to those skilled in the art that modifications and variations can be made without departing from the spirit and scope of the invention as defined by the appended claims.

What is claimed is:

1. A method for growing an indium gallium nitride by metal organic chemical vapor deposition comprising: growing the indium gallium nitride at a rate of at least about 1.5 nm/min and at a temperature of at least about 800° C. while maintaining an MOCVD reactor at an internal pressure of about 400 mbar or less.

2. The method according to claim 1, wherein the growth rate of the indium gallium nitride is at least about 2 nm/min.

3. The method according to claim 1, wherein the internal pressure of the MOCVD reactor is about 300 mbar or less.

4. The method according to claim 1, wherein the growth temperature of the indium gallium nitride is about 820° C. or more.
